(19) United States
(12) Patent Application Publication
(10) Pub. No.: US 2016/0043037 A1
(43) Pub. Date: Feb. 11, 2016

(54) MARK, SEMICONDUCTOR DEVICE, AND SEMICONDUCTOR WAFER

(71) Applicant: Kabushiki Kaisha Toshiba, Minato-ku (JP)

(72) Inventors: Shinichi NAKAGAWA, Yokohama (JP); Nobuhiro KOMINE, Nagoya (JP); Yoshinori HAGIO, Kuwana (JP); Kentaro KASA, Kawasaki (JP)

(73) Assignee: Kabushiki Kaisha Toshiba, Minato-ku (JP)

(21) Appl. No.: 14/580,472

(22) Filed: Dec. 23, 2014

Related U.S. Application Data
(60) Provisional application No. 62/033,849, filed on Aug. 6, 2014.

(51) Int. Cl. H01L 23/544

(52) U.S. Cl. CPC H01L 23/544

(57) ABSTRACT

According to one embodiment, there is provided a mark comprising a first mark pattern, a second mark pattern, and an opening pattern. The first mark pattern is arranged in a lower layer of a semiconductor wafer that includes a substrate, the lower layer, an intermediate layer, and an upper layer. The second mark pattern is arranged in the upper layer. The opening pattern exposes the first mark pattern.

### CROSS-REFERENCE TO RELATED APPLICATIONS

This application is based upon and claims the benefit of priority from U.S. Provisional Application No. 62/033,849, filed on Aug. 6, 2014; the entire contents of which are incorporated herein by reference.

### FIELD

Embodiments described herein relate generally to a mark, a semiconductor device, and a semiconductor wafer.

### BACKGROUND

Conventionally, in processes for manufacturing a semiconductor device, there is included an inspection process performed to a semiconductor wafer. The semiconductor wafer includes a substrate and a plurality of layers laminated thereon. Each of the layers of the semiconductor wafer is formed with a device pattern and an overlay mark provided for each shot region. In the inspection process for the semiconductor wafer, the overlay mark is used to inspect a positional deviation of the device pattern between the layers.

As miniaturization of device patterns advances, it has become necessary to use a scanning electron microscope (SEM) with high resolution performance to inspect positional deviations of device patterns.

### BRIEF DESCRIPTION OF THE DRAWINGS

FIG. 1 is a diagram showing a configuration of an overlay mark according to a first embodiment;

FIG. 2 is a sectional view taken along a line A-A in FIG. 1;

FIG. 3 is a plan view showing a lower layer depicted in FIG. 2;

FIG. 4 is a plan view showing intermediate layers depicted in FIG. 2;

FIG. 5 is a plan view showing an upper layer depicted in FIG. 2;

FIG. 6 is a flow chart showing a method for inspecting a device pattern positional deviation amount in a semiconductor device;

FIG. 7 is a diagram showing a configuration of an overlay mark according to a second embodiment;

FIG. 8 is a sectional view taken along a line B-B in FIG. 7;

FIG. 9 is a plan view showing a lower layer depicted in FIG. 8;

FIG. 10 is a plan view showing intermediate layers depicted in FIG. 8;

FIG. 11 is a plan view showing an upper layer depicted in FIG. 8; and

FIG. 12 is a plan view showing a protective layer depicted in FIG. 8.

### DETAILED DESCRIPTION

In general, according to one embodiment, there is provided a mark comprising a first mark pattern, a second mark pattern, and an opening pattern. The first mark pattern is arranged in a lower layer of a semiconductor wafer that includes a substrate, the lower layer, an intermediate layer, and an upper layer. The second mark pattern is arranged in the upper layer. The opening pattern exposes the first mark pattern.

Exemplary embodiments of an overlay mark and semiconductor wafer will be explained below in detail with reference to the accompanying drawings. The present invention is not limited to the following embodiments.

### First Embodiment

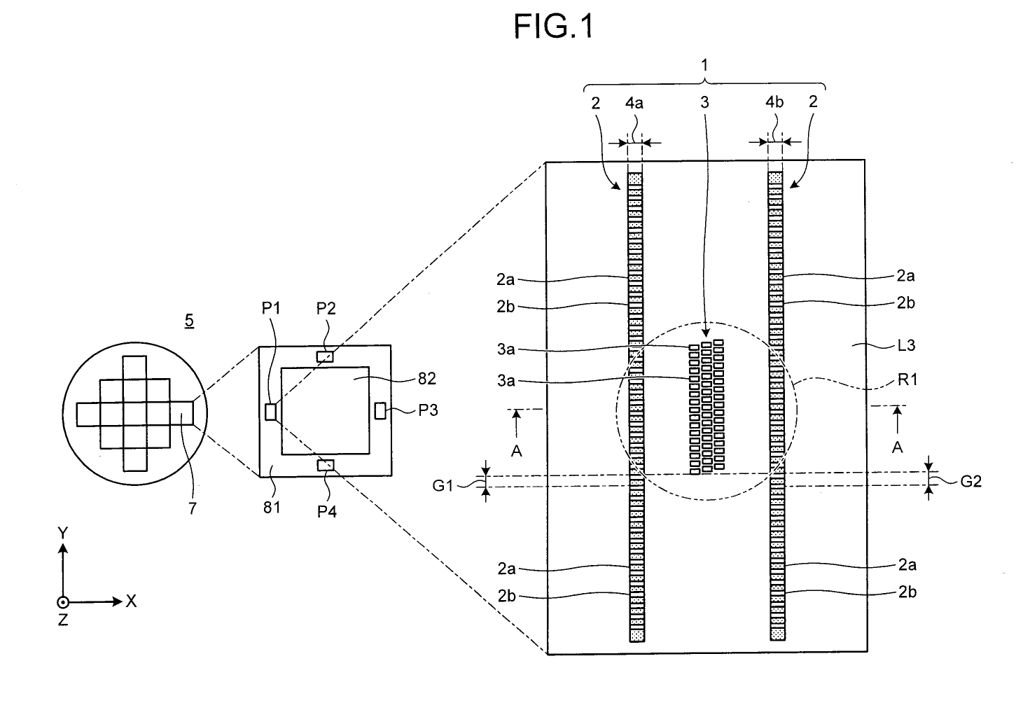

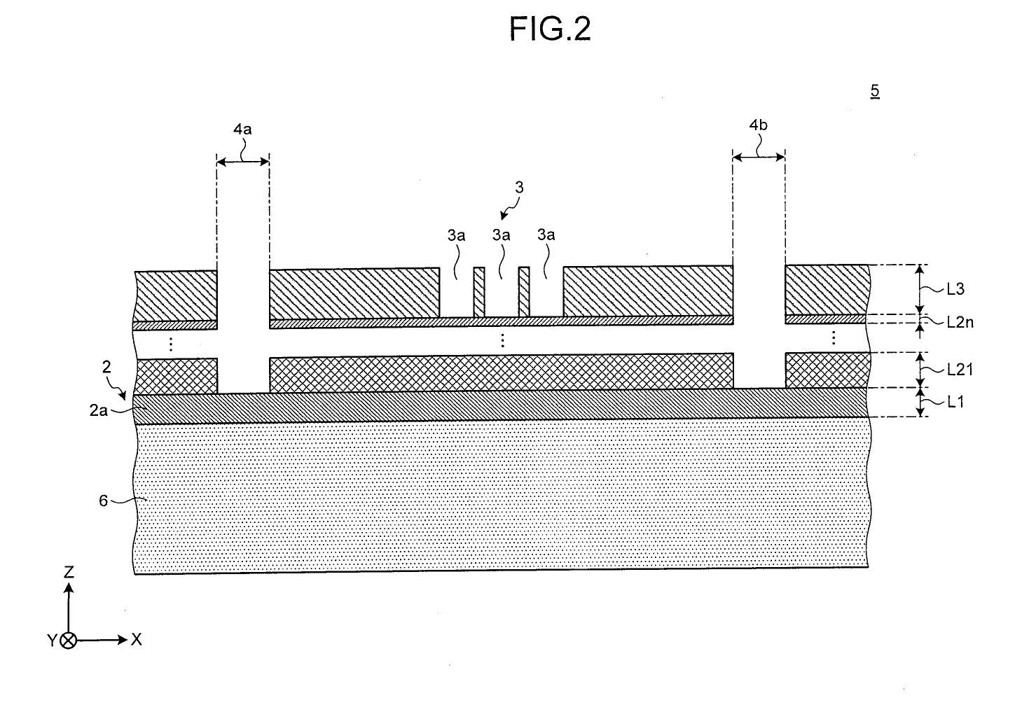

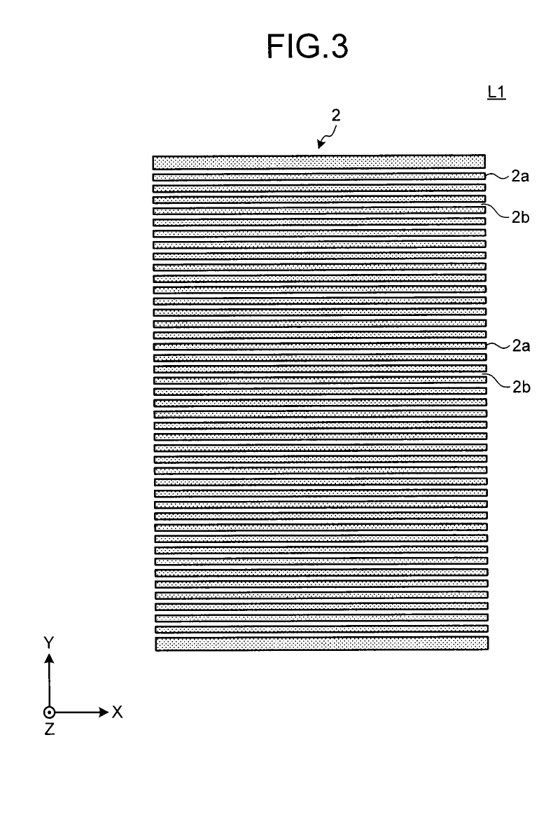

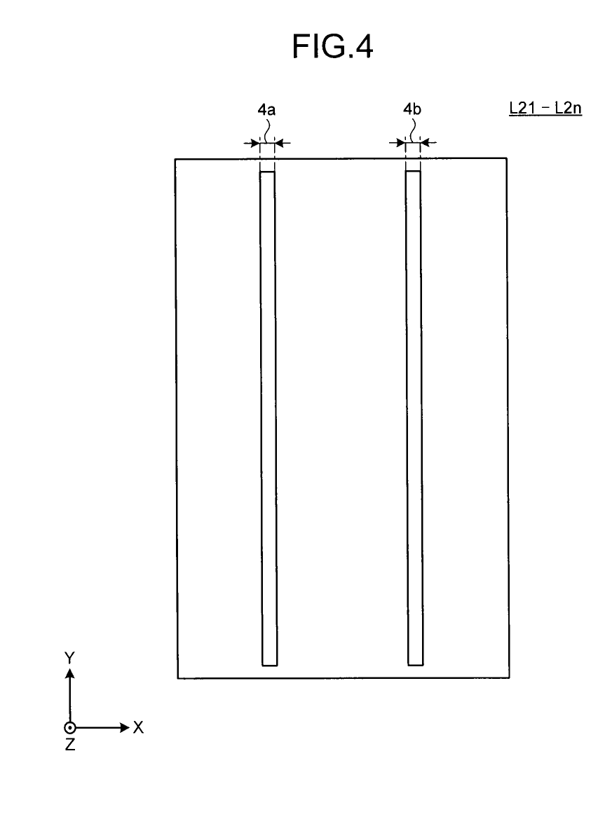

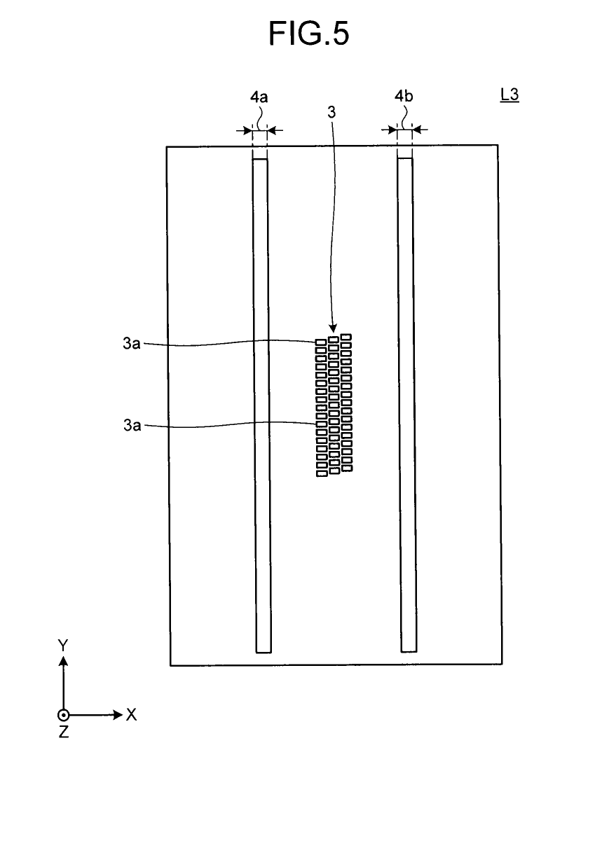

FIG. 1 is a diagram showing a configuration of an overlay mark 1 according to a first embodiment. FIG. 2 is a sectional view taken along a line A-A depicted in FIG. 1. FIG. 3 is a plan view showing a lower layer L1 depicted in FIG. 2. FIG. 4 is a plan view showing intermediate layers L21 to L2n depicted in FIG. 2. FIG. 5 is a plan view showing an upper layer L3 depicted in FIG. 2. As shown in FIG. 1, a semiconductor wafer 5 includes a plurality of shot regions 7, each of which has rectangular shape, for example. Each of the shot regions 7 includes a scribe line (calf region) 81 and a semiconductor chip region (device pattern region) 82. The scribe line 81 is a region serving as a cut path for separating the semiconductor chip region 82 from the semiconductor wafer 5. The semiconductor chip region 82 is a region to become a main portion of a semiconductor chip (semiconductor device) after it is separated from the semiconductor wafer 5. The semiconductor chip region 82 is formed with a device pattern (not shown). The overlay mark 1 is arranged in the scribe line 81 of the semiconductor wafer 5. It should be noted that the separated semiconductor chip (semiconductor device) can include the device pattern region 82 and the overlay mark 1. The overlay mark 1 shown in FIG. 1 can be arranged at a position P1 of the scribe line 81, but it may be arranged at any of other positions P2 to P4. It should be noted that, hereinafter, two directions orthogonal to each other along the surface of the semiconductor wafer 5 are referred to as an X-direction and a Y-direction, and a direction orthogonal to the surface of the semiconductor wafer 5 is referred to as a Z-direction.

As shown in FIGS. 1 and 2, in each of the shot regions 7 of the semiconductor wafer 5, a lower layer L1, intermediate layers L21 to L2n in which the number of layers is “n” (“n” is an integer that satisfies n≧1), and an upper layer L3 are laminated in this order in the Z-direction on a substrate 6. Each of the layers L1 to L3 is formed with a device pattern (not shown) in the semiconductor chip region 82. It should be noted that another layer (not shown) may be interposed between the substrate 6 and the lower layer L1.

As shown in FIG. 1, the overlay mark 1 includes a lower layer mark pattern 2, an upper layer mark pattern 3, and opening patterns 4a and 4b. As shown in FIGS. 2 and 3, the lower layer mark pattern 2 is arranged in the lower layer L1. The lower layer mark pattern 2 includes a plurality of line patterns 2a and a plurality of space patterns 2b interposed between the line patterns 2a. In other words, the lower layer mark pattern 2 includes line-and-space patterns. Each of the line patterns 2a is a remained pattern of the lower layer L1. The line patterns 2a extend in the X-direction and are arrayed in the Y-direction. Each of the space patterns 2b is a removed pattern of the lower layer L1. The lower layer mark pattern 2 has dimensions almost equal to those of a device pattern arranged in the lower layer L1 (which is not shown, but will be referred to as “lower layer device pattern”). In other words, the lower layer mark pattern 2 has dimensions that are much smaller than resolution limit of an optical microscope.

As shown in FIGS. 2 and 5, the upper layer mark pattern 3 is arranged in the upper layer L3. The upper layer mark pattern 3 includes a plurality of hole patterns 3a. Each of the hole patterns 3a is a removed pattern of the upper layer L3. The hole patterns 3a are arranged in the X-direction and in the Y-direction. The upper layer mark pattern 3 has dimensions almost equal to those of a device pattern arranged in the upper layer L3 (which is not shown, but will be referred to as “upper layer device pattern”). In other words, the upper layer mark pattern 3 has dimensions that are much smaller than resolution limit of an optical microscope.

There is a case where the lower layer mark pattern 2 and the upper layer mark pattern 3 of the overlay mark 1 shown in FIG. 1 are miniaturized to a level that cannot be recognized by the resolution of an optical microscope, in order to exclude the influence of aberrations in relation to the lower layer device pattern and the upper layer device pattern that are in a miniaturized state. In this case, it is necessary to use an SEM, which is higher in resolution than the optical microscope, to recognize the lower layer mark pattern 2 and the upper layer mark pattern 3. When an SEM is used like this, an electron beam emitted from the SEM needs to reach both of the lower layer mark pattern 2 and the upper layer mark pattern 3. In light of this, the overlay mark 1 includes the opening patterns 4a and 4b to recognize the lower layer mark pattern 2.

As shown in FIG. 2, the opening patterns 4a and 4b are formed by making openings in the upper layer L3 and the intermediate layers L21 to L2n, so that an electron beam emitted from the SEM reaches the lower layer mark pattern 2. Accordingly, the opening patterns 4a and 4b penetrate the upper layer L3 and the intermediate layers L21 to L2n and reach the lower layer L1.

The opening patterns 4a and 4b are formed by processing a plurality of layers L21 to L3 by means of, e.g., dry etching, so that they penetrate these layers. At this time, there is a case where the opening patterns 4a and 4b are formed such that their dimensions on the lower layer side are smaller than their dimensions on the upper layer side. As regards an opening that penetrates a plurality of layers, such a difference between the dimensions on the upper layer side and the dimensions on the lower layer side will be referred to as “processing conversion difference”. Because of the influence of the processing conversion difference, if the dimensions of the opening patterns 4a and 4b in the upper layer L3 are too small, the dimensions of the opening patterns 4a and 4b in the intermediate layer L21 becomes smaller than the required dimensions. Accordingly, in consideration of the influence of the processing conversion difference, the dimensions of the opening patterns 4a and 4b in the upper layer L3 are designed to cause the dimensions of the opening patterns 4a and 4b in the intermediate layer L21 to be the required dimensions.

As shown in FIG. 1, the lower layer mark pattern 2 is exposed by the opening patterns 4a and 4b. The respective line patterns 2a of the lower layer mark pattern 2 exposed by the opening pattern 4a are correlated with predetermined hole patterns 3a of the plurality of hole patterns 3a of the upper layer mark pattern 3, so that they serve as patterns for evaluating the positional deviation amount between the lower layer device pattern and the upper layer device pattern. FIG. 1 shows an example of a positional deviation amount G1 in the Y-direction between a line pattern 2a and a hole pattern 3a, which are correlated with each other as mentioned above. The positional deviation amount G1 is utilized as a parameter for calculating the positional deviation amount in the Y-direction between the lower layer device pattern and the upper layer device pattern for when these patterns are overlaid with each other (which will be referred to as “device pattern positional deviation amount”).

The respective line patterns 2a of the lower layer mark pattern 2 exposed by the opening pattern 4b are also correlated with predetermined hole patterns 3a of the plurality of hole patterns 3a of the upper layer mark pattern 3. FIG. 1 shows an example of a positional deviation amount G2 in the Y-direction between a line pattern 2a and a hole pattern 3a, which are correlated with each other as mentioned above. The positional deviation amount G2 is also utilized as a parameter for calculating the device pattern positional deviation amount in the Y-direction.

It should be noted that, if the overlay mark 1 shown in FIG. 1 is rotated by 90° as a whole to be placed at, for example, the position P2 or position P4, the positional deviation amounts G1 and G2 can be utilized as parameters for calculating a device pattern positional deviation amount in the X-direction.

As a comparative example, it is assumed that there are some discrepancies between the dimensions of the lower layer device pattern and the dimensions of the lower layer mark pattern 2 and between the dimensions of the upper layer device pattern and the dimensions of the upper layer mark pattern 3. The influence of aberrations exerted in measuring the positional deviation amount between the lower layer device pattern and the upper layer device pattern is different from the influence of aberrations exerted in measuring the positional deviation amounts G1 and G2 between the lower layer mark pattern 2 and the upper layer mark pattern 3. In this case, the positional deviation amounts G1 and G2 cannot be equivalent to the positional deviation amount between the lower layer device pattern and the upper layer device pattern. On the other hand, according to the first embodiment, the dimensions of the lower layer device pattern and the dimensions of the lower layer mark pattern 2 are set almost equal to each other. Further, the dimensions of the upper layer device pattern and the dimensions of the upper layer mark pattern 3 are set almost equal to each other. In this case, the influence of aberrations exerted in measuring the positional deviation amount between the lower layer device pattern and the upper layer device pattern becomes almost equal to the influence of aberrations exerted in measuring the positional deviation amounts G1 and G2 between the lower layer mark pattern 2 and the upper layer mark pattern 3. Consequently, the positional deviation amounts G1 and G2 can be equivalent to the positional deviation amount between the lower layer device pattern and the upper layer device pattern. In other words, when the dimensions of the lower layer mark pattern 2 and the dimensions of the upper layer mark pattern 3 are set almost equal to the dimensions of the lower layer device pattern and the dimensions of the upper layer device pattern, the positional deviation amounts G1 and G2 can be parameters with higher accuracy, as compared with the comparative example.

As shown in FIG. 1, the opening patterns 4a and 4b are arranged adjacent to the upper layer mark pattern 3, so that they can be caught within the visual field range R1 of the SEM together with the upper layer mark pattern 3. With this adjacent arrangement, the lower layer mark pattern 2 and the upper layer mark pattern 3 that are in a miniaturized state can be recognized simultaneously and accurately by the SEM. Consequently, the positional deviation amounts G1 and G2 can be accurately measured by the SEM.

As shown in FIG. 1, the dimensions of the opening patterns 4a and 4b in the Y-direction are preferably designed to expose at least two line patterns 2a of the lower layer mark pattern 2. With this configuration, the respective line patterns 2a exposed by the opening pattern 4a can be compared and can be easily discriminated as to how they extend. Similarly, the respective line patterns 2a exposed by the opening pattern 4b can be compared and can be easily discriminated as to how they extend. Thus, the positional deviation amounts G1 and G2 can be accurately measured by this discrimination.

As shown in FIG. 1, the overlay mark 1 includes the two opening patterns 4a and 4b. Accordingly, the positional deviation amounts G1 and G2 are measured through the opening patterns 4a and 4b. The overlay mark 1 may further include one or more other opening patterns to expose the lower layer mark pattern 2, in addition to the opening patterns 4a and 4b. When the overlay mark 1 includes a plurality of opening patterns (including the opening patterns 4a and 4b) as described above, sampling points for calculating the positional deviation amount can be easily increased. Consequently, device pattern positional deviation amounts can be calculated with higher accuracy by use of the overlay mark 1.

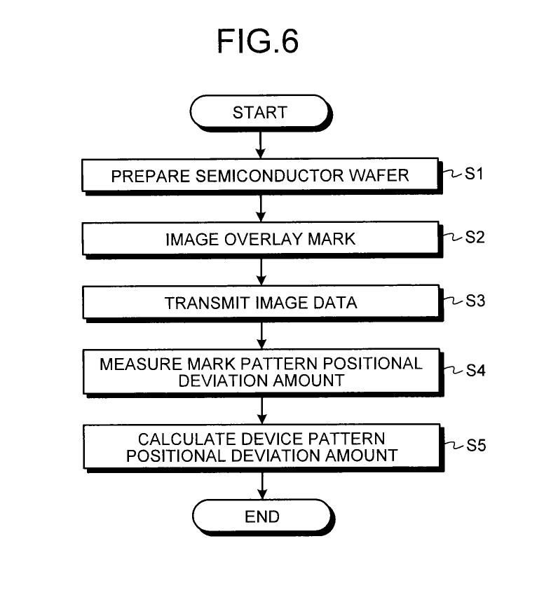

Next, an explanation will be given of a method for inspecting a device pattern positional deviation amount on the semiconductor wafer 5 shown in FIG. 1. FIG. 6 is a flow chart showing a method for inspecting a positional deviation amount of a miniaturized device pattern on the semiconductor wafer 5. At first, the semiconductor wafer 5 shown in FIG. 1 is prepared (step S1). The semiconductor wafer 5 is prepared by forming the plurality of layers L1 to L3 including the device patterns and the overlay mark 1 on the substrate 6. The overlay mark 1 has dimensions set almost equal to those of the miniaturized device patterns to exclude the influence of aberrations, as described above. Then, an SEM with high resolution performance is used to image the overlay mark 1 on the semiconductor wafer 5 (step S2). At this time, the SEM images a plurality of line patterns 2a and space patterns 2b of the lower layer mark pattern 2 exposed by the opening patterns 4a and 4b of the overlay mark 1, within its visual field range R1, together with a plurality of hole patterns 3a of the upper layer mark pattern 3. Then, the SEM transmits the image data to an arithmetic processor, such as a computer (step S3). Thereafter, based on this image data, the arithmetic processor measures the positional deviation amount G1 between a line pattern 2a of the lower layer mark pattern 2 recognized through the opening pattern 4a and a hole pattern 3a of the upper layer mark pattern 3 correlated with this line pattern 2a. Similarly, the arithmetic processor measures the positional deviation amount G2 between a line pattern 2a of the lower layer mark pattern 2 recognized through the opening pattern 4b and a hole pattern 3a of the upper layer mark pattern 3 correlated with this line pattern 2a (step S4). After the arithmetic processor measures the positional deviation amounts G1 and G2, it evaluates the positional deviation amounts G1 and G2 in accordance with a predetermined evaluation method, and calculates a device pattern positional deviation amount on the semiconductor wafer 5 (step S5).

According to the first embodiment, the overlay mark 1 includes the lower layer mark pattern 2 arranged in the lower layer L1, the upper layer mark pattern 3 arranged in the upper layer L3, and the opening patterns 4a and 4b configured to expose the lower layer mark pattern 2. Accordingly, an electron beam emitted from the SEM can reach the lower layer mark pattern 2 through the opening patterns 4a and 4b. Thus, the positional deviation amounts G1 and G2 between the lower layer mark pattern 2 and the upper layer mark pattern 3 can be measured by use of the SEM, so that a positional deviation amount of a miniaturized device pattern can be calculated with high accuracy.

### Second Embodiment

An overlay mark according to a second embodiment has a feature such that configuration of its mark pattern is different from configuration of mark pattern of the overlay mark 1 according to the first embodiment. Along with this feature, configuration of its opening pattern is also different.

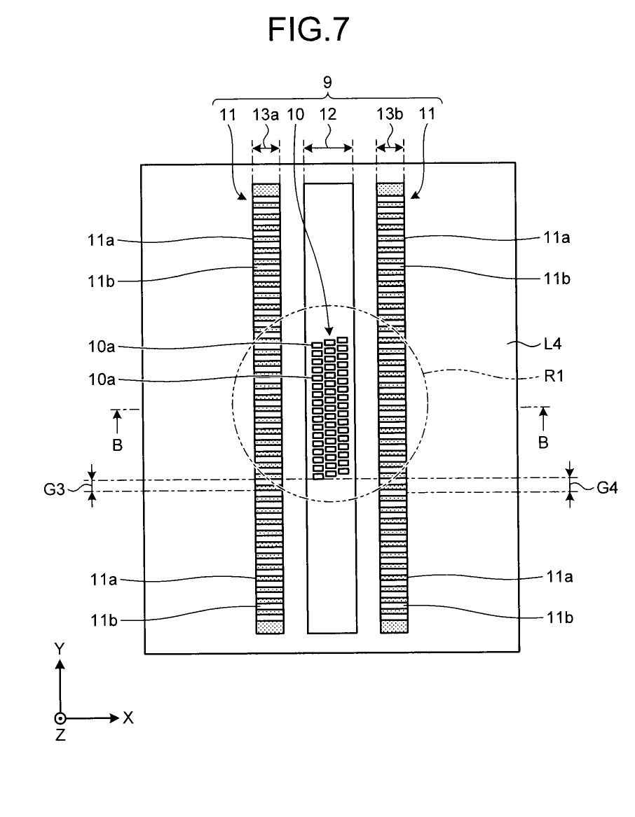

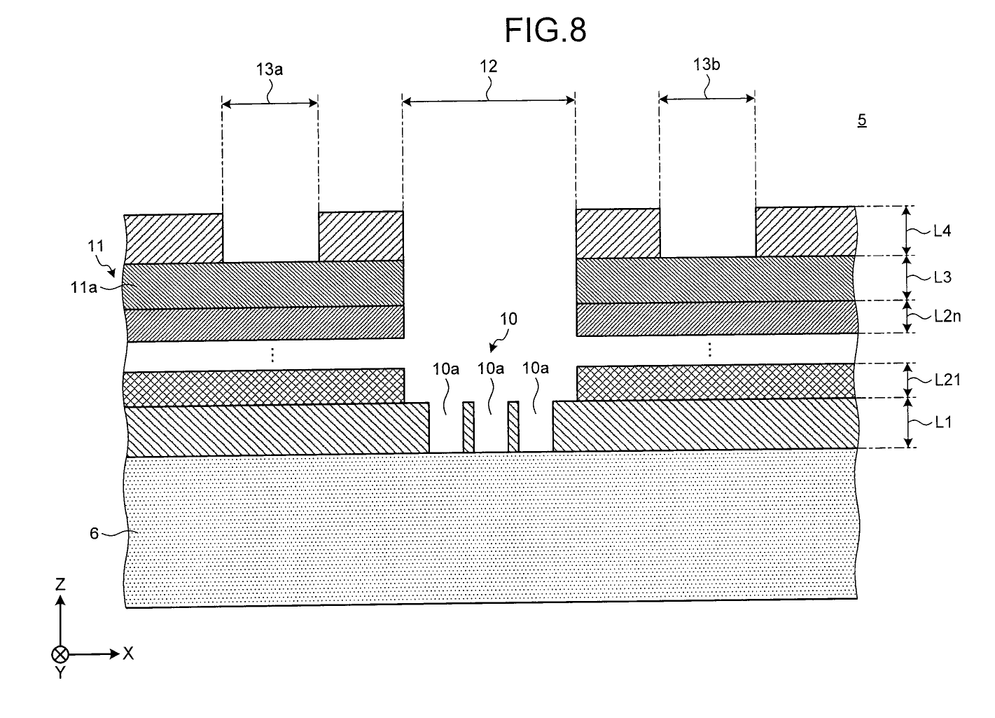

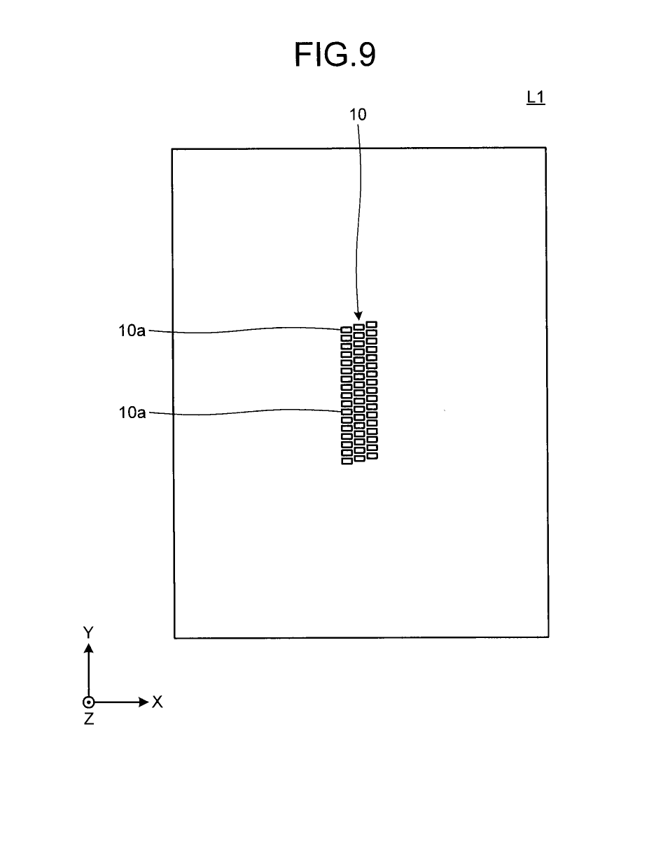

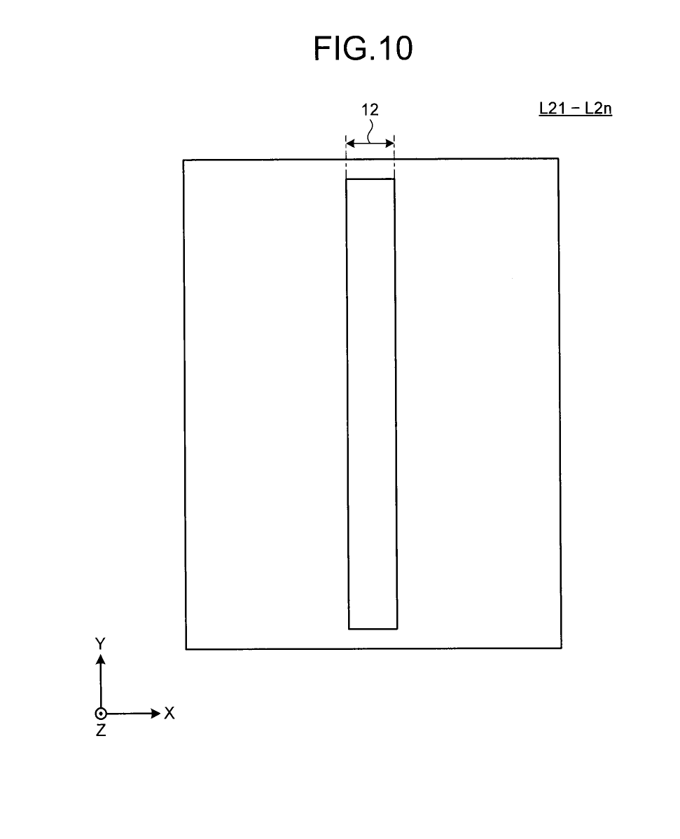

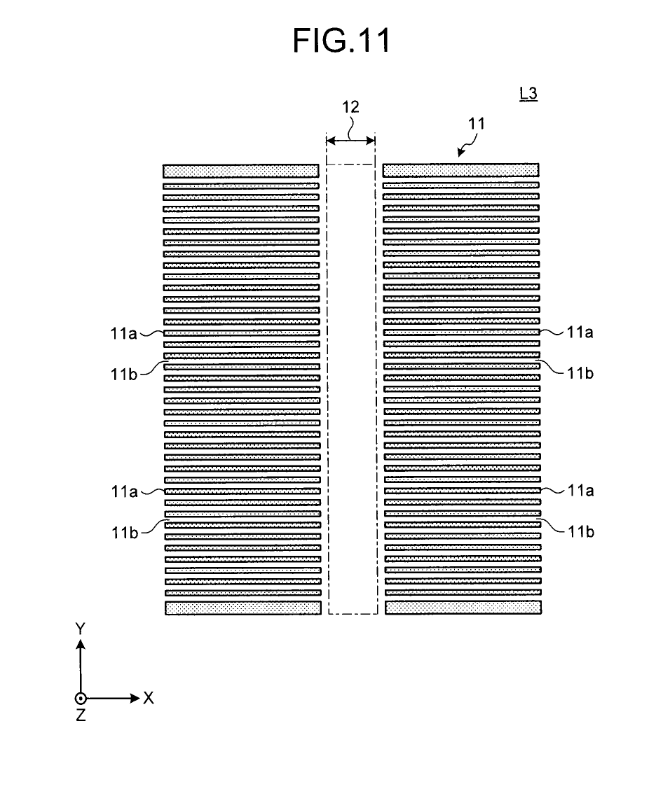

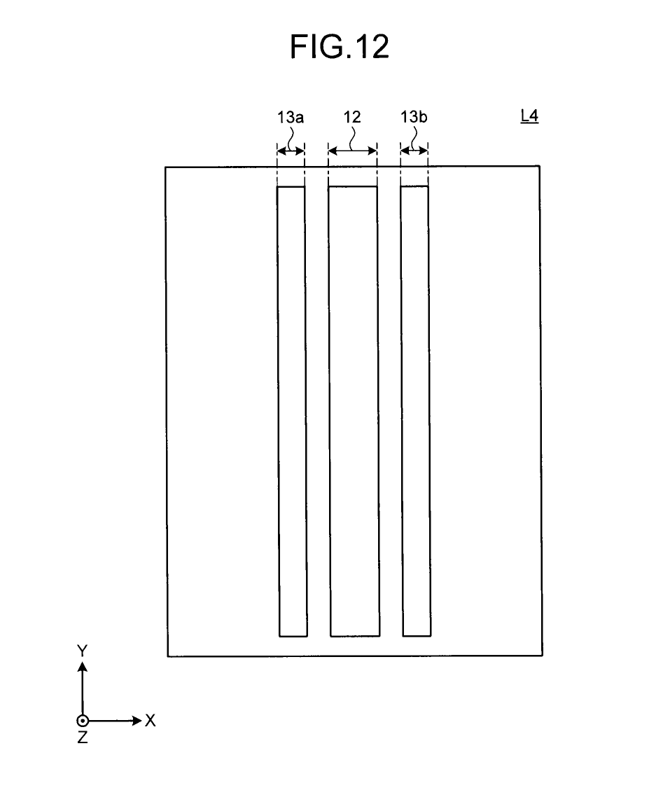

FIG. 7 is a diagram showing a configuration of an overlay mark 9 according to a second embodiment. FIG. 8 is a sectional view taken along a line B-B in FIG. 7. FIG. 9 is a plan view showing a lower layer L1 depicted in FIG. 8. FIG. 10 is a plan view showing intermediate layers L21 to L2n depicted in FIG. 8. FIG. 11 is a plan view showing an upper layer L3 depicted in FIG. 8. FIG. 12 is a plan view showing a protective layer L4 depicted in FIG. 8. The overlay mark 9 shown in FIG. 7 according to the second embodiment can be also arranged in the scribe line 81 of the semiconductor wafer 5 shown in FIG. 1, as in the first embodiment. The overlay mark 9 shown in FIG. 7 can be arranged at the position P1 of the scribe line 81 shown in FIG. 1, but it may be arranged at any of other positions P2 to P4. Further, as shown in FIG. 8, the protective layer L4 for protecting the upper layer L3 is laminated on the upper layer L3; which is due to the manufacturing process of the semiconductor wafer 5. For example, the protective layer L4 is made of a material excellent in etching resistance. Hereinafter in this embodiment, similar components to those of the first embodiment are denoted by the same reference symbols, and their repetitive descriptions will be omitted.

As shown in FIG. 7, the overlay mark 9 includes a lower layer mark pattern 10, an upper layer mark pattern 11, and opening patterns 12, 13a, and 13b.

As shown in FIGS. 8 and 9, the lower layer mark pattern 10 is arranged in the lower layer L1. The lower layer mark pattern 10 includes a plurality of hole patterns 10a. Each of the hole patterns 10a can be a removed pattern of the lower layer L1. The hole patterns 10a are arranged in the X-direction and in the Y-direction. The lower layer mark pattern 10 has dimensions almost equal to dimensions of a lower layer device pattern. In other words, the lower layer mark pattern 10 has dimensions that are much smaller than resolution limit of an optical microscope.

As shown in FIGS. 8 and 11, the upper layer mark pattern 11 is arranged in the upper layer L3. The upper layer mark pattern 11 includes a plurality of line patterns 11a and a plurality of space patterns 11b interposed between the line patterns 11a. In other words, the upper layer mark pattern 11 includes line-and-space patterns. Each of the line patterns 11a is a remained pattern of the upper layer L3. The line patterns 11a extend in the X-direction and are arrayed in the Y-direction. Each of the space patterns 11b is a removed pattern of the upper layer L3. As described later, the upper layer mark pattern 11 is divided by the opening pattern 12 near the center, so that an electron beam emitted from an SEM reaches the lower layer mark pattern 10. In other words, the opening pattern 12 penetrates the upper layer mark pattern 11 such that the lower layer mark pattern 10 is exposed. The upper layer mark pattern 11 has dimensions almost equal to those of an upper layer device pattern. In other words, the upper layer mark pattern 11 has dimensions that are much smaller than resolution limit of an optical microscope.

There is a case where the lower layer mark pattern 10 and the upper layer mark pattern 11 of the overlay mark 9 shown in FIG. 7 are miniaturized, as in the first embodiment, in consideration of the influence of aberrations. In this case, it is necessary to use an SEM, which is higher in resolution than the optical microscope, to recognize the lower layer mark pattern 10 and the upper layer mark pattern 11. When an SEM is used like this, an electron beam emitted from the SEM needs to reach both of the lower layer mark pattern 10 and the upper layer mark pattern 11. In light of this, the overlay mark 9 includes the opening patterns 12, 13a, and 13b to recognize the lower layer mark pattern 10 and the upper layer mark pattern 11.

As shown in FIGS. 8 and 10 to 12, the opening pattern 12 is formed by making openings in the protective layer L4, the upper layer L3, and the intermediate layers L21 to L2n, so that an electron beam emitted from the SEM can reach the lower layer mark pattern 10. Accordingly, the opening pattern 12 penetrates the protective layer L4, the upper layer L3, and the intermediate layers L21 to L2n and reaches the lower layer L1. Further, in consideration of the influence of the processing conversion difference, the dimensions of the opening pattern 12 in the protective layer L4 are designed to cause the dimensions of the opening pattern 12 in the intermediate layer L21 to be the required dimensions.

As shown in FIGS. 8 and 12, the opening patterns 13a and 13b are formed by making openings in the protective layer L4, so that an electron beam emitted from the SEM reaches the upper layer mark pattern 11. Accordingly, the opening patterns 13a and 13b penetrate the protective layer L4 and reach the upper layer L3.

As shown in FIG. 7, the lower layer mark pattern 10 is exposed by the opening pattern 12. The upper layer mark pattern 11 is exposed by the opening patterns 13a and 13b. The respective line patterns 11a of the upper layer mark pattern 11 exposed by the opening pattern 13a are correlated with predetermined hole patterns 10a of the plurality of hole patterns 10a of the lower layer mark pattern 10 exposed by the opening pattern 12, so that they serve as patterns for evaluating the positional deviation amount between the lower layer device pattern and the upper layer device pattern. FIG. 7 shows an example of a positional deviation amount G3 in the Y-direction between a line pattern 11a and a hole pattern 10a, which are correlated with each other as mentioned above. The positional deviation amount G3 is utilized as a parameter for calculating a device pattern positional deviation amount in the Y-direction.

The respective line patterns 11a of the lower layer mark pattern 11 exposed by the opening pattern 13b are also correlated with predetermined hole patterns 10a of the plurality of hole patterns 10a of the lower layer mark pattern 10 exposed by the opening pattern 12. FIG. 7 shows an example of a positional deviation amount G4 in the Y-direction between a line pattern 11a and a hole pattern 10a, which are correlated with each other as mentioned above. The positional deviation amount G4 is also utilized as a parameter for calculating the device pattern positional deviation amount in the Y-direction.

If the overlay mark 9 shown in FIG. 7 is rotated by 90° as a whole to be placed at, for example, the position P2 or position P4 shown in FIG. 1, the positional deviation amounts G3 and G4 can be utilized as parameters for calculating a device pattern positional deviation amount in the X-direction.

As described above, the dimensions of the lower layer device pattern and the dimensions of the lower layer mark pattern 10 are set almost equal to each other. Further, the dimensions of the upper layer device pattern and the dimensions of the upper layer mark pattern 11 are set almost equal to each other. In this case, the influence of aberrations exerted in measuring the positional deviation amount between the lower layer device pattern and the upper layer device pattern becomes almost equal to the influence of aberrations exerted in measuring the positional deviation amounts G3 and G4 between the lower layer mark pattern 10 and the upper layer mark pattern 11. Consequently, the positional deviation amounts G3 and G4 are equivalent to the positional deviation amount between the lower layer device pattern and the upper layer device pattern. Thus, as in the first embodiment, the positional deviation amounts G3 and G4 can be parameters with higher accuracy.

As shown in FIG. 7, the opening patterns 13a and 13b are arranged adjacent to the opening pattern 12, so that they can be caught within the visual field range R1 of the SEM together with the opening pattern 12. With this adjacent arrangement, the lower layer mark pattern 10 and the upper layer mark pattern 11 that are in a miniaturized state can be recognized accurately by the SEM. Consequently, the positional deviation amounts G3 and G4 can be accurately measured by the SEM.

As shown in FIG. 7, the dimensions of the opening pattern 12 in the Y-direction are preferably designed to expose at least two hole patterns 10a of the lower layer mark pattern 10. With this configuration, the respective hole patterns 10a exposed by the opening pattern 12 can be compared and can be easily discriminated as to how they are formed. Further, the dimensions of the opening patterns 13a and 13b in the Y-direction are preferably designed to expose at least two line patterns 11a of the upper layer mark pattern 11. With this configuration, the respective line patterns 11a exposed by the opening patterns 13a and 13b can be compared and can be easily discriminated as to how they extend. Thus, the positional deviation amounts G3 and G4 can be accurately measured by discriminating the hole patterns 10a and the line patterns 11a, as described above.

As shown in FIG. 7, the overlay mark 9 includes the two opening patterns 13a and 13b that expose the upper layer mark pattern 11. Accordingly, the positional deviation amounts G3 and G4 are measured through the opening patterns 13a and 13b. The overlay mark 9 may further include one or more other opening patterns to expose the upper layer mark pattern 11, in addition to the opening patterns 13a and 13b. When the overlay mark 9 includes a plurality of opening patterns (including the opening patterns 13a and 13b) as described above, sampling points for calculating the positional deviation amount can be easily increased. Consequently, device pattern positional deviation amounts can be calculated with higher accuracy by use of the overlay mark 9.

When the overlay mark 9 is used to inspect a positional deviation amount of a miniaturized device pattern on the semiconductor wafer 5, steps of the flow is similar to steps of the flow shown in FIG. 6. At first, the SEM images the overlay mark 9 from the semiconductor wafer 5 and transmits this image data to an arithmetic processor (steps S1 to S3). Then, the arithmetic processor measures the positional deviation amounts G3 and G4, each of which is between a hole pattern 10a of the lower layer mark pattern 10 recognized through the opening pattern 12 and a line pattern 11a of the upper layer mark pattern 11 correlated with this hole pattern 10a (step S4). Then, the arithmetic processor evaluates the measurement results of the positional deviation amounts G3 and G4 in accordance with a predetermined evaluation method, and calculates a device pattern positional deviation amount on the semiconductor wafer 5 (step S5).

According to the second embodiment, the overlay mark 9 includes the lower layer mark pattern 10 formed on the lower layer L1 and the opening pattern 12 arranged to expose the lower layer mark pattern 10. Accordingly, an electron beam emitted from the SEM can reach the lower layer mark pattern 10 through the opening pattern 12. Further, the overlay mark 9 includes the upper layer mark pattern 11 formed on the upper layer L3 and the opening patterns 13a and 13b penetrating the protective layer L4 to expose the upper layer mark pattern 11. Accordingly, an electron beam emitted from the SEM can reach the upper layer mark pattern 11 through the opening patterns 13a and 13b. Thus, the positional deviation amounts G3 and G4 between the lower layer mark pattern 10 and the upper layer mark pattern 11 can be measured by use of the SEM, so that a positional deviation amount of a miniaturized device pattern can be calculated with high accuracy. Particularly, the overlay mark 9 can be applied to inspect a device pattern positional deviation amount in a case where the protective layer L4 is formed above the upper layer mark pattern 11 due to the manufacturing process of the semiconductor wafer 5.

It should be noted that, in the overlay mark 9, the upper layer mark pattern 11 may be formed on one of the intermediate layers L21 to L2n in place of the upper layer L3. In this case, the two opening patterns 13a and 13b are formed to penetrate the protective layer L4, the upper layer L3, and those of the intermediate layers L21 to L2n which are present above the intermediate layer including the upper layer mark pattern 11. With this configuration, an electron beam emitted from the SEM can be radiated onto the upper layer mark pattern 11 through the two opening patterns 13a and 13b.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A mark comprising a first mark pattern, a second mark pattern, and an opening pattern,
the first mark pattern being arranged in a lower layer of a semiconductor wafer that includes a substrate, the lower layer, an intermediate layer, and an upper layer,
the second mark pattern being arranged in the upper layer, and
the opening pattern exposing the first mark pattern.

2. The mark according to claim 1, wherein
the first mark pattern includes a plurality of line patterns and a plurality of space patterns interposed between the plurality of line patterns, and
the second mark pattern includes a plurality of hole patterns.

3. The mark according to claim 2, wherein
the first mark pattern has dimensions almost equal to dimensions of part of a device pattern formed in the lower layer, and
the second mark pattern has dimensions almost equal to dimensions of part of a device pattern formed in the upper layer.

4. The mark according to claim 2, wherein
the opening pattern and the second mark pattern are arranged such that the opening pattern and the second mark pattern can be caught together within a visual field range of a scanning electron microscope.

5. The mark according to claim 4, wherein
the opening pattern exposes at least two of the plurality of line patterns.

6. The mark according to claim 2, wherein
the mark comprises a plurality of the opening patterns.

7. The mark according to claim 1, wherein
the first mark pattern includes a plurality of hole patterns, and
the second mark pattern includes a plurality of line patterns and a plurality of space patterns interposed between the plurality of line patterns.

8. The mark according to claim 7, wherein
the first mark pattern has dimensions almost equal to dimensions of part of a device pattern arranged in the lower layer, and
the second mark pattern has dimensions almost equal to dimensions of part of a device pattern arranged in the upper layer.

9. The mark according to claim 7, wherein
the opening pattern exposes at least two of the plurality of hole patterns.

10. The mark according to claim 7, further comprising a second opening pattern that exposes the second mark pattern.

11. The mark according to claim 10, wherein
the second opening pattern exposes at least two of the plurality of line patterns.

12. The mark according to claim 10, wherein
the mark comprises a plurality of the second opening patterns.

13. The mark according to claim 10, wherein
the second opening pattern and the opening pattern are arranged such that the second opening pattern and the opening pattern can be caught together within a visual field range of a scanning electron microscope.

14. The mark according to claim 10 wherein
the second opening pattern exposes the second mark pattern.

15. A semiconductor device comprising a device pattern region and a mark,
the mark comprising a first mark pattern, a second mark pattern, and an opening pattern,
the first mark pattern being arranged in a lower layer of the semiconductor device that includes a substrate, the lower layer, an intermediate layer, and an upper layer,
the second mark pattern being arranged in the upper layer, and
the opening pattern exposing the first mark pattern.

16. The semiconductor device according to claim 15, wherein
the first mark pattern includes a plurality of line patterns and a plurality of space patterns interposed between the plurality of line patterns, and
the second mark pattern includes a plurality of hole patterns.

17. The semiconductor device according to claim 15, wherein
the first mark pattern includes a plurality of hole patterns, and
the second mark pattern includes a plurality of line patterns and a plurality of space patterns interposed between the plurality of line patterns.

18. A semiconductor wafer having a plurality of semiconductor devices each comprising a device pattern region and a mark,
the semiconductor wafer including a substrate, a lower layer, an intermediate layer, and an upper layer,
the mark comprising a first mark pattern, a second mark pattern, and an opening pattern,
the first mark pattern being arranged in the lower layer,
the second mark pattern being arranged in the upper layer, and
the opening pattern exposing the first mark pattern.

19. The semiconductor wafer according to claim 18, wherein
the first mark pattern includes a plurality of line patterns and a plurality of space patterns interposed between the plurality of line patterns, and
the second mark pattern includes a plurality of hole patterns.

20. The semiconductor wafer according to claim 18, wherein
the first mark pattern includes a plurality of hole patterns, and
the second mark pattern includes a plurality of line patterns and a plurality of space patterns interposed between the plurality of line patterns.
